(19) United States
(12) Patent Application Publication
(10) Pub. No.: US 2012/0188734 A1
(43) Pub. Date: Jul. 26, 2012

(54) WIRING BOARD AND METHOD FOR MANUFACTURING THE SAME

(75) Inventors: Yukinobu MIKADO, Ogaki-shi (JP); Shunsuke Sakai, Ogaki-shi (JP); Kazuhiro Yoshikawa, Ogaki-shi (JP)

(73) Assignee: IBIDEN CO., LTD., Ogaki-shi (JP)

(21) Appl. No.: 13/332,463

(22) Filed: Dec. 21, 2011

(30) Foreign Application Priority Data
Jan. 20, 2011 (JP) 2011-010311

(51) Int. Cl. H05K 1/02; H05K 3/10; H05K 3/32

(52) U.S. Cl. 361/761; 29/832; 29/837

(57) ABSTRACT

A wiring board including an insulative substrate having a cavity portion, an electronic device positioned in the cavity portion of the insulative substrate, an interlayer insulation layer made of an insulative material and formed on the insulative substrate and on the electronic device, and a conductive layer having a conductive pattern and formed on the interlayer insulation layer. The insulative substrate has a gap formed with respect to the electronic device in the cavity portion, the gap between the electronic device in the cavity portion and the insulative substrate is filled with an insulator made of the insulative material derived from the interlayer insulation layer, and the conductive pattern of the conductive layer has an enlarged-width portion across and directly over the gap.

### CROSS-REFERENCE TO RELATED APPLICATIONS

The present application is based on and claims the benefit of priority to Japanese Patent Application No. 2011-010311, filed Jan. 20, 2011. The contents of the specification, scope of patent claims and drawings in Japanese Patent Application No. 2011-10311 are incorporated herein by reference in their entirety in this application.

### BACKGROUND OF THE INVENTION

1. Field of the Invention

The present invention relates to a wiring board and its manufacturing method.

2. Discussion of the Background

Japanese Laid-Open Patent Publication No. 2007-266197 describes a wiring board which includes an insulative substrate where a cavity is formed, a capacitor arranged in the cavity and positioned in a side direction of the insulative substrate, an interlayer insulation layer positioned on the insulative substrate and on the capacitor, and a conductive layer positioned on the interlayer insulation layer. The insulative material from the interlayer insulation layer is filled in a gap between the insulative substrate and the capacitor in the cavity. The entire contents of Japanese Laid-Open Patent Publication No. 2007-266197 are incorporated herein by reference.

### SUMMARY OF THE INVENTION

According to one aspect of the present invention, a wiring board includes an insulative substrate having a cavity portion, an electronic device positioned in the cavity portion of the insulative substrate, an interlayer insulation layer made of an insulative material and formed on the insulative substrate and on the electronic device, and a conductive layer having a conductive pattern and formed on the interlayer insulation layer. The insulative substrate has a gap formed with respect to the electronic device in the cavity portion, the gap between the electronic device in the cavity portion and the insulative substrate is filled with an insulator made of the insulative material derived from the interlayer insulation layer, and the conductive pattern of the conductive layer has an enlarged-width portion across and directly over the gap.

According to another aspect of the present invention, a method for manufacturing a wiring board includes preparing an insulative substrate having a cavity portion, positioning an electronic device in the cavity portion of the insulative substrate, forming an interlayer insulation layer made of an insulative material on the insulative substrate and on the electronic device, filling a gap between the insulative substrate and the electronic device in the cavity portion with an insulator made of the insulative material derived from the interlayer insulation layer, and forming a conductive layer having a conductive pattern on the interlayer insulation layer. The forming of the conductive layer includes forming an enlarged-width portion across and directly over the gap between in the insulative substrate and the electronic device.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring board according to an embodiment of the present invention;

FIG. 2 is a cross-sectional view of a capacitor to be built into a wiring board according to the embodiment of the present invention;

FIG. 3 is a plan view showing the position and shape of a capacitor accommodated in a cavity in a wiring board according to the embodiment of the present invention;

FIG. 4 is a magnified view of a recess formed in an interlayer insulation layer in FIG. 1;

FIG. 5 is a plan view showing the shapes of conductive patterns whose widths are partially enlarged in a wiring board according to the embodiment of the present invention;

FIG. 6 is a magnified view of a conductive pattern shown in FIG. 5;

FIG. 7 is a view showing a width-enlarging angle of a conductive pattern shown in FIG. 6;

FIG. 8 is a flowchart showing a method for manufacturing a wiring board according to the embodiment of the present invention;

FIG. 9 is, in the manufacturing method shown in FIG. 8, a view to illustrate a step for preparing a core substrate (insulative substrate);

FIG. 10A is, in the manufacturing method shown in FIG. 8, a view to illustrate a first step for forming a cavity;

FIG. 10B is, in the manufacturing method shown in FIG. 8, a view to illustrate a second step for forming a cavity;

FIG. 11 is, in the manufacturing method shown in FIG. 8, a view showing the core substrate after the cavity is formed;

FIG. 12 is, in the manufacturing method shown in FIG. 8, a view to illustrate a step for attaching the core substrate having the cavity to a carrier;

FIG. 13 is, in the manufacturing method shown in FIG. 8, a view to illustrate a step for positioning a capacitor in the cavity;

FIG. 14 is, in the manufacturing method shown in FIG. 8, a view showing a state where a capacitor is positioned in the cavity;

FIG. 15 is, in the manufacturing method shown in FIG. 8, a view to illustrate a step for forming a first interlayer insulation layer and a first copper foil on the insulative substrate and on the capacitor;

FIG. 16A is, in the manufacturing method shown in FIG. 8, a view to illustrate a pressing step;

FIG. 16B is a view showing a state subsequent to the pressing in FIG. 16A;

FIG. 17 is, in the manufacturing method shown in FIG. 8, a view to illustrate a step for forming a second interlayer insulation layer and a second copper foil on the insulative substrate and on the capacitor after removing the carrier;

FIG. 18A is, in the manufacturing method shown in FIG. 8, a view to illustrate a first step for forming conductive layers on the first and second interlayer insulation layers and for electrically connecting each conductive layer and electrodes of the capacitor to each other;

FIG. 18B is a view to illustrate a second step subsequent to the step in FIG. 18A;

FIG. 19 is a view to illustrate a third step subsequent to the step in FIG. 18B;

FIG. 20 is a view showing a state where an electronic component is mounted on a surface of a wiring board according to the embodiment of the present invention;

FIG. 21A is a view of a first alternative example showing the shape of an enlarged-width portion in a wiring board according to the embodiment of the present invention;

FIG. 21B is a view of a second alternative example showing the shape of an enlarged-width portion in a wiring board according to the embodiment of the present invention;

FIG. 22A is a view showing a first alternative example of a width-enlarging angle in a wiring board according to the embodiment of the present invention;

FIG. 22B is a view showing a second alternative example of a width-enlarging angle in a wiring board according to the embodiment of the present invention;

FIG. 23 is a plan view showing a wiring board having multiple conductive patterns with enlarged-width portions of different shapes in another embodiment of the present invention;

FIG. 24 is a view showing another shape of a conductive pattern formed near a recess in a wiring board according to the embodiment of the present invention;

FIG. 25 is a view showing another shape of a cavity in a wiring board according to the embodiment of the present invention;

FIG. 26 is a view showing a wiring board in which another wiring board is built instead of an electronic component in yet another embodiment of the present invention;

FIG. 27 is a view showing a wiring board having a simpler structure in yet another embodiment of the present invention;

FIG. 28 is a view showing a single-sided wiring board in yet another embodiment of the present invention;

FIG. 29 is a view showing a wiring board having a further multilayer structure in yet another embodiment of the present invention; and

FIG. 30 is a view showing a wiring board with a built-in IC chip in yet another embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction in a wiring board (or a thickness direction of the wiring board), corresponding to a direction along a normal line to the main surfaces (upper and lower surfaces) of the wiring board. On the other hand, arrows (X1, X2) and (Y1, Y2) each indicate a direction perpendicular to a lamination direction (or a direction to a side of each layer). The main surfaces of a wiring board are on the X-Y plane. Side surfaces of a wiring board are on the X-Z plane or the Y-Z plane.

Two main surfaces facing opposite directions of a normal line are referred to as a first surface or a third surface (the Z1-side surface) and a second surface or a fourth surface (the Z2-side surface). In lamination directions, the side closer to the core is referred to as a lower layer (or inner-layer side), and the side farther from the core is referred to as an upper layer (or outer-layer side). In addition, a side farther from a cavity (in particular its gravity center) on the X-Y plane is referred to as outside, and the side closer to the cavity as inside. “Directly over” means a direction Z (Z1 side or Z2 side). A planar shape means a shape on the X-Y plane unless otherwise indicated specifically.

Conductive layers are those formed with one or more conductive patterns. Conductive layers may include a conductive pattern that forms an electrical circuit such as wiring (including ground), a pad or land, and the like, or may include a planar conductive pattern that does not form an electrical circuit.

Opening portions include notches and cuts other than holes and grooves. Holes are not limited to penetrating holes, and non-penetrating holes are also referred to as holes. Holes include via holes and through holes. Hereinafter, conductor formed in a via hole (wall or bottom surface) is referred to as a via conductor, and conductor formed in a through hole (wall surface) is referred to as a through-hole conductor.

Plating includes wet plating such as electrolytic plating as well as dry plating such as PVD (physical vapor deposition) and CVD (chemical vapor deposition).

Preparing includes situations in which material and components are purchased and manufactured accordingly as well as situations in which finished products are purchased and used accordingly.

Positioning an electronic device in a cavity includes situations in which the entire electronic device is completely accommodated in a cavity as well as situations in which only part of an electronic device is positioned in a cavity.

“Connection” includes connecting with a joint as well as connecting without a joint. Connecting with a joint includes situations in which two objects formed separately are bonded by an adhesive or the like, for example. Connecting without a joint includes situations in which two portions are formed to be contiguous (integrated) and nothing is present between them, for example.

In the following, an embodiment of the present invention is described in detail with reference to the drawings.

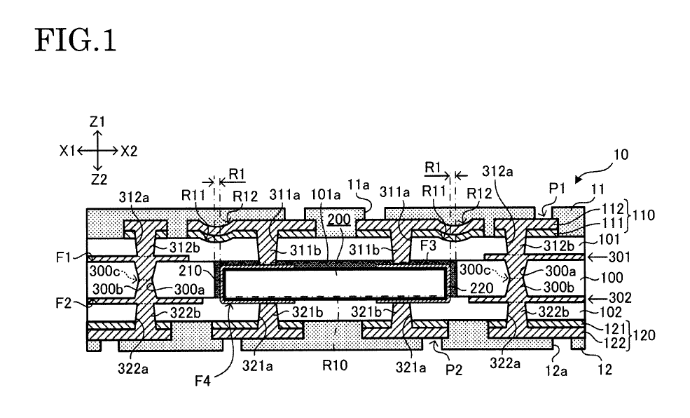

As shown in FIG. 1, wiring board 10 according to the present embodiment has substrate 100 (insulative substrate), insulation layers (101, 102) (interlayer insulation layers), conductive layers (110, 120), electronic component 200 (electronic device) and solder resists (11, 12). Electronic component 200 is built into wiring board 10. Wiring board 10 of the present embodiment is a rigid wiring board. However, wiring board 10 may be a flexible wiring board. In the following, one of upper and lower surfaces of substrate 100 (two main surfaces) is referred to as first surface (F1) and the other as second surface (F2). Also, of upper and lower surfaces (two main surfaces) of electronic component 200, the surface facing the same direction as first surface (F1) is referred to as third surface (F3), and the other as fourth surface (F4).

Substrate 100 is insulative, and becomes the core substrate of wiring board 10. Through hole (300a) is formed in substrate 100 (core substrate), and through-hole conductor (300b) is formed by filling plating (such as copper plating) in through hole (300a). Through-hole conductor (300b) is shaped like an hourglass, for example. Namely, through-hole conductor (300b) has narrowed portion (300c), and the width of through-hole conductor (300b) gradually decreases from first surface (F1) toward narrowed portion (300c), and gradually decreases from second surface (F2) toward narrowed portion (300c). However, the shape of through-hole conductor (300b) is not limited to such, and may be substantially a column, for example.

Conductive layer 301 is formed on first surface (F1) of substrate 100, and conductive layer 302 is formed on second surface (F2) of substrate 100. Conductive layers (301, 302) each include a land of through-hole conductor (300b).

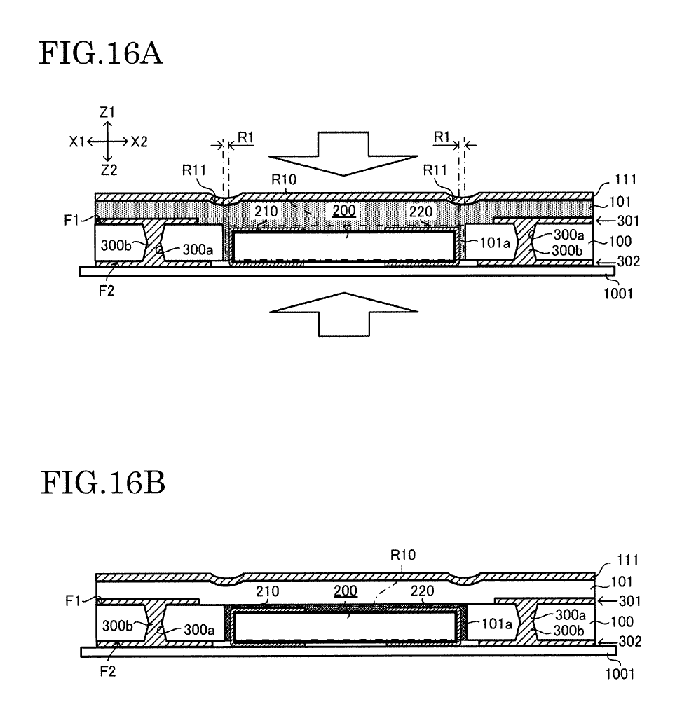

Cavity (R10) is formed in substrate 100, and electronic component 200 is accommodated in cavity (R10). Electronic component 200 is positioned in a side direction of substrate 100 (direction X or direction Y) by being positioned in cavity (R10). In the present embodiment, substantially the entire electronic component 200 is completely accommodated in cavity (R10). However, that is not the only option, and only part of electronic component 200 may be positioned in cavity (R10). In the present embodiment, insulator (101a) is filled in a gap between substrate 100 and electronic component 200 in cavity (R10). In the present embodiment, insulator (101a) is made from the insulative material (resin, in particular) of upper insulation layer 101 (resin insulation layer, in particular) (see FIG. 16A). Insulator (101a) has a higher thermal expansion coefficient than either of substrate 100 and electronic component 200. Insulator (101a) completely covers electronic component 200. Accordingly, electronic component 200 is protected by insulator (101a) (resin), while being fixed to a predetermined position.

Insulation layer 101 is formed on first surface (F1) of substrate 100 and on third surface (F3) of electronic component 200. Insulation layer 102 is formed on second surface (F2) of substrate 100 and on fourth surface (F4) of electronic component 200. Cavity (R10) is a hole that penetrates through substrate 100. Insulation layer 101 covers one opening (the first-surface (F1) side) of cavity (R10) (hole), and insulation layer 102 covers the other opening (the second-surface (F2) side) of cavity (R10) (hole). Conductive layer 110 is formed on insulation layer 101, and conductive layer 120 is formed on insulation layer 102. In the present embodiment, conductive layers (110, 120) are the outermost layers. However, that is not the only option, and more interlayer insulation layers and conductive layers may further be formed (see later-described FIG. 29).

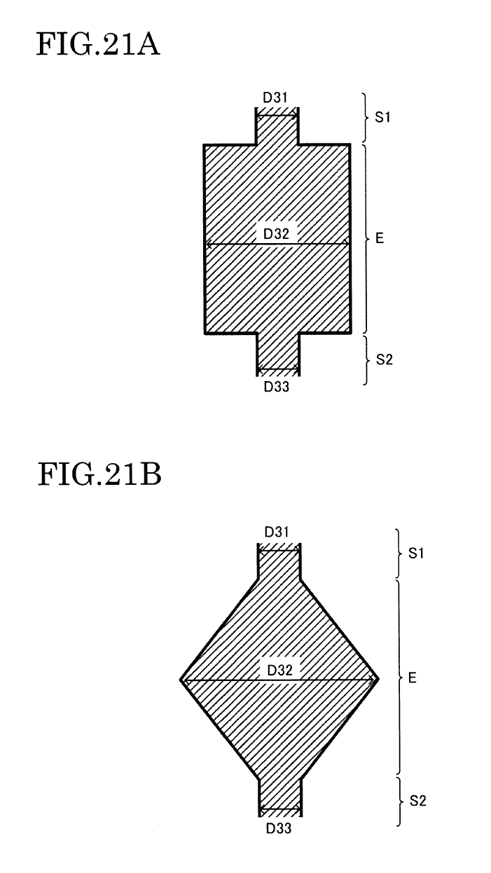

Conductive layer 110 is the outermost conductive layer on the first-surface (F1) side, and conductive layer 120 is the outermost conductive layer on the second-surface (F2) side. Solder resists (11, 12) are respectively formed on conductive layers (110, 120). However, opening portions (11a, 12a) are respectively formed in solder resists (11, 12). Therefore, a predetermined position of conductive layer 110 (the position corresponding to opening portion (11a)) is exposed without being covered by solder resist 11 to become pad (P1). Also, a predetermined position of conductive layer 120 (the position corresponding to opening portion (12a)) becomes pad (P2). Pad (P1) becomes an external connection terminal for electrical connection with another wiring board, for example, and pad (P2) becomes an external connection terminal for mounting an electronic component, for example (see later-described FIG. 20). However, pads (P1, P2) may be used in any other way.

In the present embodiment, pads (P1, P2) have an anticorrosion layer made of Ni/Au film, for example, on their surfaces. Anticorrosion layers may be formed by electrolytic plating, sputtering or the like. Alternatively, anticorrosion layers made of organic preservative film may be formed by an OSP treatment. An anticorrosion layer is not always required and it may be omitted unless necessary.

Holes (311a, 312a) (via holes) are formed in insulation layer 101, and holes (321a, 322a) (via holes) are formed in insulation layer 102. By filling conductor (such as copper plating) in holes (311a, 312a, 321a, 322a), the conductor in each hole respectively becomes via conductors (311b, 312b, 321b, 322b) (filled conductors). Holes (311a, 321a) each reach electrodes (210, 220) of electronic component 200, and via conductors (311b, 321b) are each electrically connected to electrodes (210, 220) of electronic component 200 either from the first-surface (F1) side or from the second-surface (F2) side of substrate 100. As described, electronic component 200 is connected to via conductors (311b, 321b) from both of its surfaces in the present embodiment. In the following, such a structure is referred to as a double-sided via structure.

In the above double-sided via structure, electrodes (210, 220) of electronic component 200 and conductive layer 110 on insulation layer 101 are electrically connected to each other by via conductors (311b), and electrodes (210, 220) of electronic component 200 and conductive layer 120 on insulation layer 102 are electrically connected to each other by via conductors (321b).

In addition, conductive layer 301 on first surface (F1) of substrate 100 and conductive layer 110 on insulation layer 101 are electrically connected to each other by via conductor (312b), and conductive layer 302 on second surface (F2) of substrate 100 and conductive layer 120 on insulation layer 102 are electrically connected to each other by via conductor (322b). Also, conductive layer 301 on first surface (F1) of substrate 100 and conductive layer 302 on second surface (F2) of substrate 100 are electrically connected to each other by through-hole conductor (300b). Via conductors (312b, 322b) and through-hole conductor (300b) are each a filled conductor, and they are stacked in direction Z.

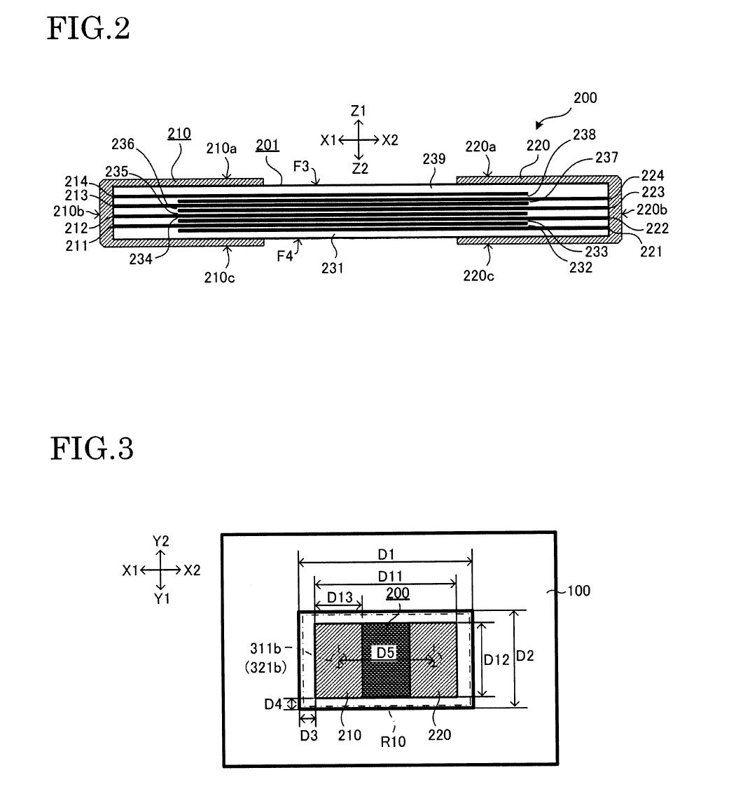

Electronic component 200 is a chip-type MLCC (multilayer ceramic capacitor) as shown in FIG. 2, for example, and has capacitor body 201 and U-shaped electrodes (210, 220). Capacitor body 201 is formed with multiple dielectric layers (231˜239) and multiple conductive layers (211˜214) and (221˜224) laminated alternately. Dielectric layers (231˜239) are each made of ceramic, for example. Electrodes (210, 220) are respectively formed on both end portions of capacitor body 201. Capacitor body 201 is covered by electrodes (210, 220) from its lower surface (the fourth-surface (F4) side surface) to a side surface and to its upper surface (the third-surface (F3) side surface). In the following, regarding electrode 210, the portion covering the upper surface of capacitor body 201 is referred to as upper portion (210a), the portion covering a side surface of capacitor body 201 as side portion (210b) and the portion covering the lower surface of capacitor body 201 as lower portion (210c). Also, regarding electrode 220, the portion covering the upper surface of capacitor body 201 is referred to as upper portion (220a), the portion covering a side surface of capacitor body 201 as side portion (220b) and the portion covering the lower surface of capacitor body 201 as lower portion (220c).

As shown in FIG. 2, since the central portion of capacitor body 201 positioned between electrode 210 and electrode 220 is not covered by electrodes (210, 220) and dielectric layers (231, 239) (ceramic) are exposed, its strength is relatively insufficient. However, when electronic component 200 is mounted on (built in) wiring board 10, since the central portion of capacitor body 201 is covered by insulator (101a) (resin) or the like, capacitor body 201 is protected by insulator (101a) or the like.

FIG. 3 shows a state in which electronic component 200 is accommodated in cavity (R10) of substrate 100 (core substrate).

Substrate 100, insulation layers (101, 102), solder resists (11, 12) and electronic component 200 are each shaped as a rectangular sheet, for example. Cavity (R10) penetrates through substrate 100. Openings on both ends of cavity (R10) (first-surface (F1) side and second-surface (F2) side) are each substantially in a rectangular shape, for example. Main surfaces of electronic component 200 are substantially in a rectangular shape, for example. In the present embodiment, electronic component 200 has a planar shape corresponding to cavity (R10) (a similar shape of substantially the same size, for example), and the thickness of electronic component 200 is substantially the same as the depth of cavity (R10) (hole). In addition, the thickness of substrate 100 is substantially the same as the thickness of electronic component 200. However, the above are not the only options, and the shape and dimensions of cavity (R10) are determined freely.

Here, an example of the preferred value for each measurement in FIG. 3 is shown.

Width (D1) of cavity (R10) in a longitudinal direction is approximately 1080 μm, for example, and width (D2) of cavity (R10) in a lateral direction is approximately 580 μm, for example. Width (D11) of electronic component 200 in a longitudinal direction is approximately 1000 μm, for example, and width (D12) of electronic component 200 in a lateral direction is approximately 500 μm, for example. Width (D3) of a gap between electronic component 200 and cavity (R10) in a longitudinal direction is approximately 40 μm (clearance is twice as much, approximately 80 μm), for example, and width (D4) of a gap between electronic component 200 and cavity (R10) in a lateral direction is approximately 40 μm (clearance is twice as much, approximately 80 μm), for example. Width (D13) of upper portion (210a) or lower portion (210c) of electrode 210 or upper portion (220a) or lower portion (220c) of electrode 220 is approximately 230 μm, for example.

Via conductor (311b) and via conductor (321b) are positioned to face each other by sandwiching electronic component 200, for example. Pitch (D5) of via conductor (311b) or (321b) is approximately 770 μm, for example.

The thickness of substrate 100 is approximately 100 μm, for example. The thickness of electronic component 200 (thickness that includes electrodes) is approximately 150 μm, for example. The thickness of wiring board 10 (thickness from solder resist 11 to solder resist 12) is approximately 290 μm, for example.

Substrate 100 is made, for example, by impregnating glass cloth (core material) with epoxy resin (hereinafter referred to as glass epoxy). The core material has a lower thermal expansion coefficient than the primary material (glass-epoxy resin in the present embodiment). As for core material, the following is considered preferable, for example: glass fiber (glass cloth or glass non-woven fabric, for example), aramid fiber (aramid non-woven fabric, for example), inorganic material such as silica filler, or the like. However, basically, the material of substrate 100 is selected freely. For example, polyester resin, bismaleimide triazine resin (BT resin), imide resin (polyimide), phenol resin, allyl polyphenylene ether resin (A-PPE resin) or the like may be used instead of epoxy resin. Substrate 100 may be formed with multiple layers made of different materials.

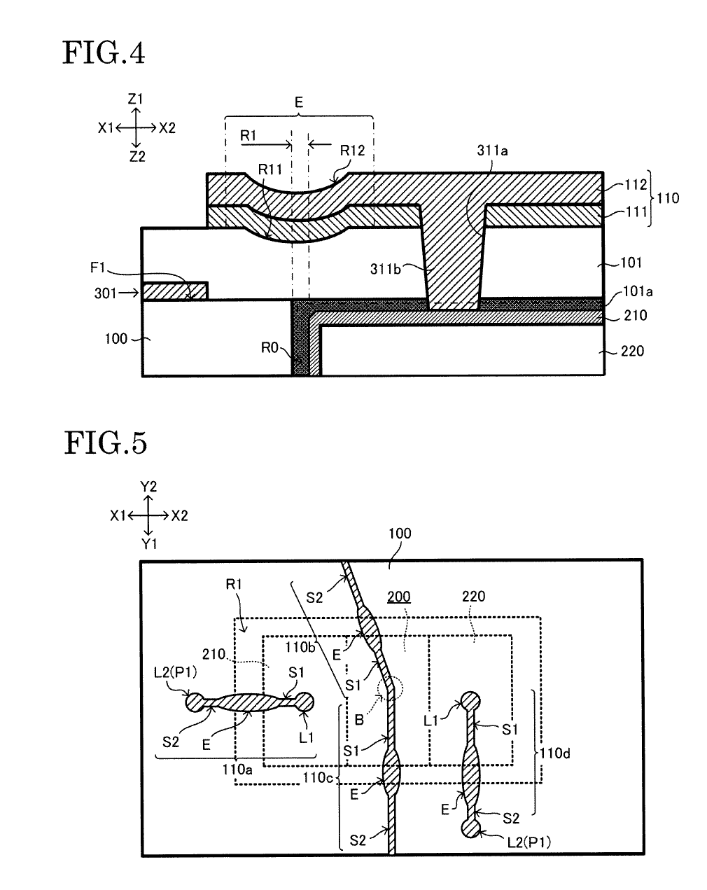

In the present embodiment, insulation layers (101, 102) are each made by impregnating core material with resin. Since insulation layer 101 is made of resin containing core material, recess (R11) is seldom formed in region (R1) of insulation layer 101 directly over gap (R0) (see FIG. 4), and the conductive pattern formed on recess (R11) is suppressed from breaking. Insulation layers (101, 102) are made of glass epoxy, for example. However, that is not the only option, and insulation layers (101, 102) may be made of resin without containing core material, for example. In addition, basically, the material of insulation layers (101, 102) may be selected freely. For example, polyester resin, bismaleimide triazine resin (BT resin), imide resin (polyimide), phenol resin, allyl polyphenylene ether resin (A-PPE resin) or the like may be used instead of epoxy resin. Each insulation layer may be formed with multiple layers made of different materials.

Via conductors (311b, 312b, 321b, 322b) are each made of copper plating, for example. Those via conductors (311b) and others are shaped in a tapered column (truncated cone), for example, tapering with a diameter that increases from substrate 100 (core substrate) or electronic component 200 toward their respective upper layers. However, the shape of via conductors is not limited to the above, and any other shape may be employed.

Conductive layer 110 is formed with copper foil 111 (lower layer) and copper plating 112 (upper layer). Conductive layer 120 is formed with copper foil 121 (lower layer) and copper plating 122 (upper layer). Conductive layers (110, 120) include wiring that forms an electrical circuit (electrical circuit that includes electronic component 200, for example), a land, a plain pattern to enhance the strength of wiring board 10, and the like.

Materials of each conductive layer and each via conductor are selected freely as long as they are conductive, and they may be metallic or non-metallic. Each conductive layer and each via conductor may be formed with multiple layers made of different materials.

In the present embodiment, insulator (101a) is filled in gap (R0) between substrate 100 and electronic component 200 in cavity (R10) as shown in FIG. 4. Insulator (101a) is the resin that has flowed out from insulation layer 101, for example (see FIG. 16A). Thus, when insulator (101a) is filled in gap (R0), recess (R11) resulting from gap (R0) is formed in region (R1) of insulation layer 101 directly over gap (R0). Namely, insulation layer 101 has recess (R11) directly over gap (R0). In addition, recess (R12) due to the shape of recess (R11) is also formed in the conductive pattern formed on recess (R11) (conductive layer 110).

In the present embodiment, conductive layer 110 has conductive patterns (110a, 110b, 110c, 110d), whose widths are partially enlarged directly over gap (R0) as shown in FIG. 5.

Specifically, those conductive patterns (110a˜110d) each have an area where first straight portion (S1), enlarged-width portion (E) and second straight portion (S2) are connected in that order. First straight portion (S1), enlarged-width portion (E) and second straight portion (S2) are connected to each other in an integrated fashion, and each works as wiring. In addition, each of conductive patterns (110a, 110d) further includes land (L1), which is electrically connected to first straight portion (S1) and which becomes a first terminal, as well as land (L2), which is electrically connected to second straight portion (S2) and which becomes a second terminal. Land (L2) works as pad (P1), for example (FIG. 1). Namely, in conductive patterns (110a, 110d), enlarged-width portion (E) is connected to pad (P1) (land (L2)) through wiring (second straight portion (S2)). Also, conductive pattern (110b) and conductive pattern (110c) are electrically connected to each other at bent portion (B). Land (L1) of conductive pattern (110a) or (110d) is electrically connected to electrode 210 or 220 of electronic component 200 by via conductor (311b) (FIG. 1).

First straight portion (S1) and second straight portion (S2) each have a substantially constant width. In the present embodiment, first straight portion (S1) is positioned inside (the side closer to electronic component 200), and second straight portion (S2) is positioned outside (the side farther from electronic component 200).

Enlarged-width portion (E) is positioned directly over gap (R0), having a width which is greater than either of first straight portion (S1) and second straight portion (S2) in substantially entirely from the connecting point with first straight portion (S1) to the connecting point with second straight portion (S2). Conductive patterns (110a˜110d) each have a width partially enlarged at enlarged-width portion (E). In the present embodiment, enlarged-width portion (E) has a greater width than recesses (R11, R12) as shown in FIG. 4. Thus, each enlarged-width portion (E) of conductive patterns (110a˜110d) (FIG. 5) is formed in recess (R11) and its vicinity (which includes at least the periphery of recess (R11)).

In the present embodiment, conductive layer 110 has conductive patterns whose widths are partially enlarged directly over gap (R0) between substrate 100 and electronic component 200 in cavity (R10). In a portion where width is enlarged (enlarged-width portion (E)), the strength of enlarged-width portion (E) is enhanced by enlarging the width of the conductive pattern. Accordingly, conductive patterns (conductive layer 110) positioned directly over gap (R0) between substrate 100 and electronic component 200 in cavity (R10) are suppressed from breaking, and electrical connection reliability is enhanced in wiring board 10.

To enhance the strength of conductive patterns, increasing the thickness of conductive patterns is an option. However, when increasing the thickness of conductive patterns, the number of plating steps needs to be increased or the like, and the manufacturing process tends to be complex. By contrast, when enlarging the width of conductive patterns, modifying a pattern (such as a resist pattern) during the patterning step is sufficient, and thus a simplified manufacturing process is easier to maintain.

To suppress breakage in conductive patterns, enlarging the entire width of conductive patterns is an option. However, if the width of conductive patterns is also enlarged even in portions where breakage seldom occurs, another issue may arise, such as a reduction of space for forming wiring.

For that matter, conductive patterns (110a˜110d) each have a width partially enlarged in region (R1) directly over gap (R0) between substrate 100 and electronic component 200 in cavity (R10) (see FIG. 5) in the present embodiment. Conductive patterns are especially prone to breakage in region (R1) directly over gap (R0) because of recess (R11) or because of differences in thermal expansion coefficients among insulator (101a) and substrate 100 and electronic component 200. By selectively enlarging the width of conductive patterns in such portions where breakage tends to occur, conductive patterns are suppressed from breakage, while wiring space is secured.

Also, to suppress breakage in conductive patterns, it is an option to form conductive patterns to avoid positioning in region (R1) directly over gap (R0) between substrate 100 and electronic component 200 in cavity (R10). However, if conductive patterns are formed to avoid region (R1), another issue may arise, such as a reduction of space for forming wiring.

For that matter, in wiring board 10 of the present embodiment, since conductive patterns are also formed in region (R1) directly over gap (R0) between electronic component 200 and substrate 100, it is easier to secure wiring space.

In the present embodiment, substrate 100 (insulative substrate) corresponds to the core substrate of wiring board 10, and pad (P2) for mounting an electronic component is formed in the outermost layer (conductive layer 120) opposite conductive layer 110 (second-surface (F2) side) (see later-described FIG. 20). Therefore, conductive layer 110 with enlarged-width portion (E) can be formed on the side opposite a surface for mounting an electronic component (the side to be connected to a motherboard, for example). Accordingly, when high-density wiring is required for an electronic component to be mounted on pad (P2), it is easier to form fine patterns for that purpose. Such fine patterns may be formed on conductive layer 120, for example.

In the present embodiment, enlarged-width portion (E) has a shape that is substantially elliptical as shown in FIG. 5. However, the shape of enlarged-width portion (E) is not limited specifically (see later-described FIGS. 21A˜23).

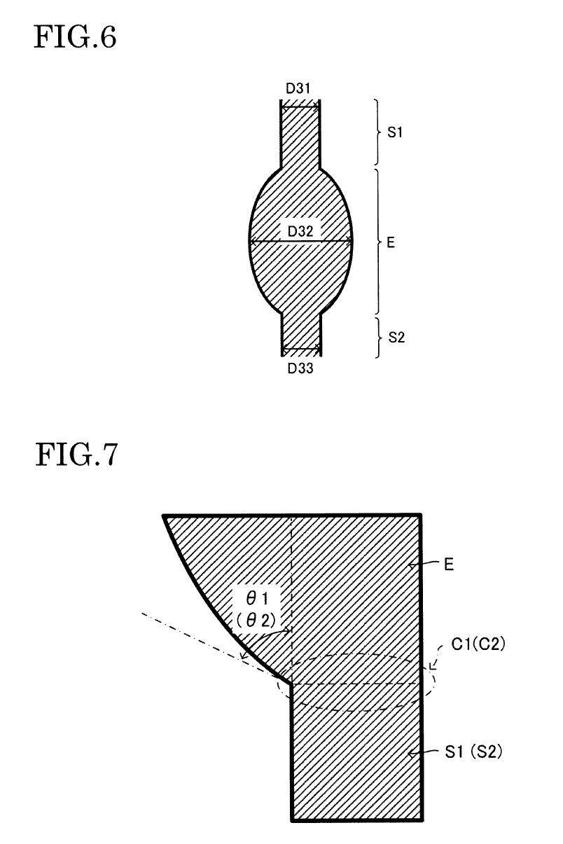

Regarding the measurements in FIG. 6, width (D32) of enlarged-width portion (E) is preferred to be in the range of approximately 1.3 times to approximately 5 times width (D31) of first straight portion (S1). In addition, it is especially preferable if width (D32) of enlarged-width portion (E) is also set in the range of approximately 1.3 times to approximately 5 times width (D33) of second straight portion (S2).

When the width of enlarged-width portion (E) is not constant as shown in FIG. 6, the maximum width of enlarged-width portion (E) corresponds to above-described width (D32), and if maximum width (width D32) of enlarged-width portion (E) is in the range of approximately 1.3 times to approximately 5 times at least width (D31) of first straight portion (S1) or width (D33) of second straight portion (S2), substantially the same effects as those described above are achieved.

In at least either connecting point (C1) of first straight portion (S1) and enlarged-width portion (E) or connecting point (C2) of second straight portion (S2) and enlarged-width portion (E), it is considered preferable for the width of conductive patterns to be enlarged at an angle less than 90 degrees. If set so, stress concentration is mitigated, and it is easier to form such portions.

If enlarged-width portion (E) has a shape that is substantially elliptical, width-enlarging angle (θ1) at connecting point (C1) or width-enlarging angle (θ2) at connecting point (C2) is determined based on a tangent at connecting point (C1) or (C2) as shown in FIG. 7. It is considered preferable if width-enlarging angle (θ1) is set less than approximately 90 degrees, and it is considered especially preferable if width-enlarging angle (θ2) is also set less than approximately 90 degrees.

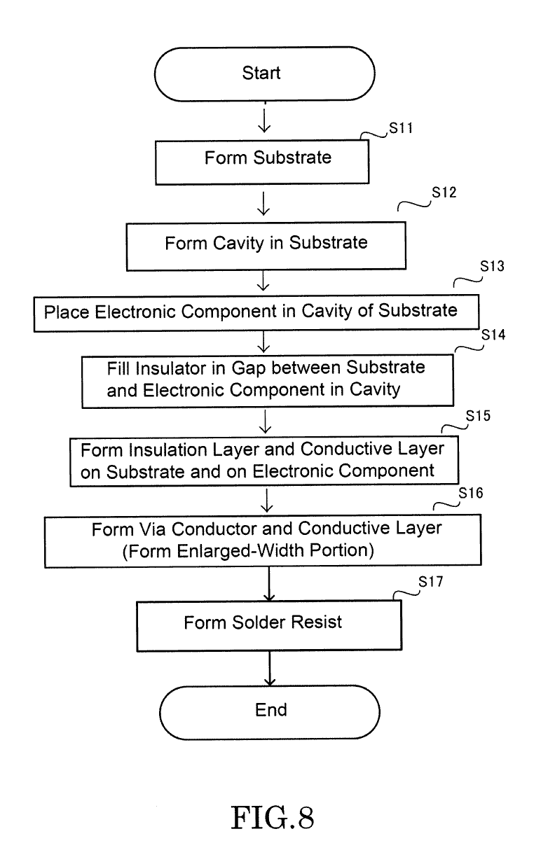

In the following, a method for manufacturing wiring board 10 is described with reference to FIG. 8 and others. FIG. 8 is a flowchart outlining the contents and order of a method for manufacturing wiring board 10 according to the present embodiment.

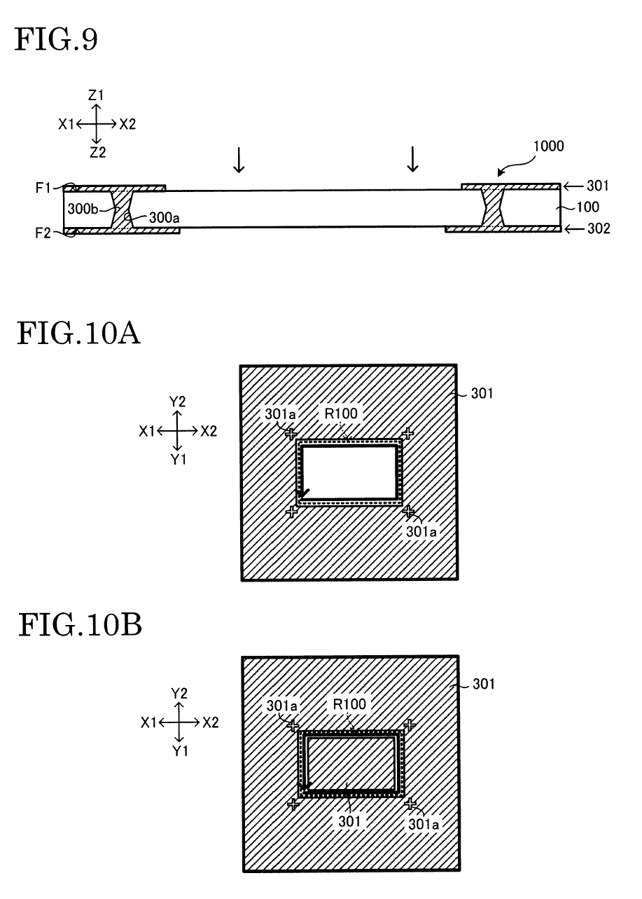

In step (S11), wiring board 1000 (starting material) is prepared as shown in FIG. 9. In the present embodiment, wiring board 1000 is formed with substrate 100 (insulative substrate), conductive layer 301 formed on first surface (F1) of substrate 100, conductive layer 302 formed on second surface (F2) of substrate 100, and through-hole conductor (300b). Substrate 100 is made of completely cured glass epoxy, for example. Conductive layers (301, 302) each have a triple-layer structure of copper foil (lower layer), electroless plating (middle layer) and electrolytic plating (upper layer), for example.

Through hole (300a) shaped like an hourglass is formed by irradiating a laser from both sides of substrate 100 (double-sided copper-clad laminate) having copper foil on both of its surfaces, for example. After copper foils are formed on substrate 100, and through hole (300a) is formed in substrate 100, conductive layers (301, 302) and through-hole conductor (300b) are formed by performing copper plating (such as electroless plating and electrolytic plating), for example.

After the above laser irradiation, it is considered preferable to conduct desmearing on through hole (300a). Unwanted conduction (short-circuiting) is suppressed by desmearing. Also, depending on requirements, it is considered preferable to roughen surfaces of conductive layers (301, 302) by etching or the like.

In the present embodiment, conductive layer 301 is not formed on substrate 100 in region (R100) which corresponds to cavity (R10), as shown in FIG. 10A. If conductive layer 301 has such a conductive pattern, since the position and shape of cavity (R10) are clear, it is easier to align laser irradiation for forming cavity (R10) in a later step (step (S12) in FIG. 8).

However, the conductive pattern of conductive layer 301 is not limited to the pattern shown in FIG. 10A. For example, as shown in FIG. 10B, it is also an option for conductive layer 301 not to be formed solely in portions on substrate 100 at which a laser is irradiated in the later step (step (S12) in FIG. 8) (hereinafter referred to as a laser irradiation path). In such a case, conductive layer 301 exists in the portion inside the laser irradiation path. Even if conductive layer 301 has such a pattern, it is easier to align laser irradiation for forming cavity (R10).

In addition, as shown in FIG. 10A, conductive layer 301 has alignment mark (301a) in the present embodiment. Alignment mark (301a) is a pattern to be optically recognized in a later step (step (S13) in FIG. 8), for example, and formed by partially removing the conductor by etching or the like. In the present embodiment, alignment marks (301a) are positioned around region (R100) (four corners, for example). However, the positions and shape of alignment marks (301a) are not limited to such and may be determined freely.

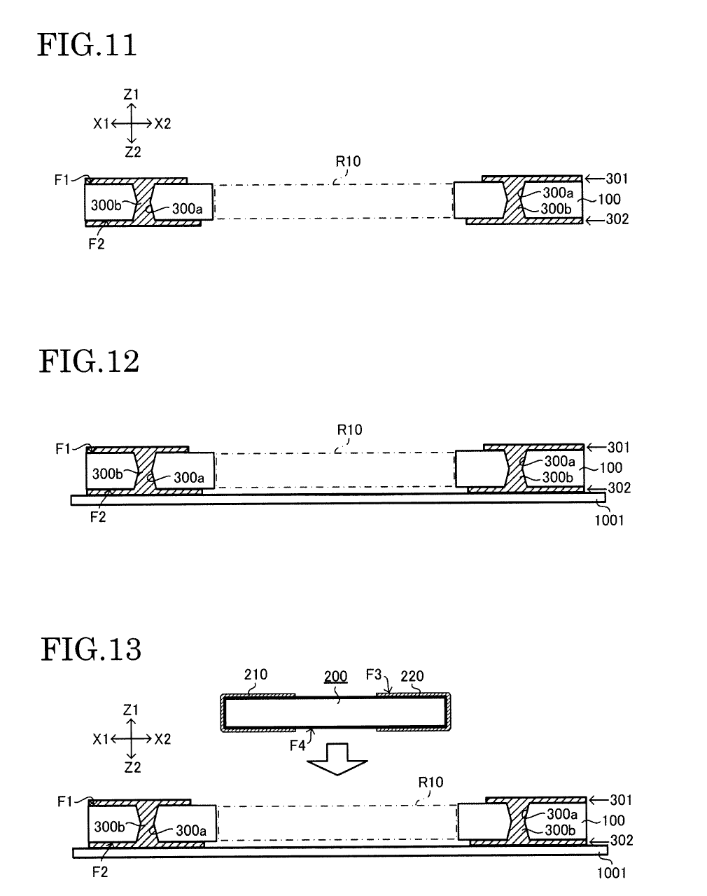

In step (S12) in FIG. 8, cavity (R10) is formed in substrate 100. Specifically, as shown in FIG. 10A, for example, a laser is irradiated to draw a rectangle so that region (R100) corresponding to cavity (R10) is cut out from its surroundings in substrate 100. The angle at which to irradiate a laser is set substantially perpendicular to first surface (F1) of substrate 100, for example. Accordingly, cavity (R10) is formed as shown in FIG. 11. Since a laser is used to form cavity (R10) in the present embodiment, it is easy to obtain cavity (R10). Cavity (R10) is a space for accommodating electronic component 200.

In step (S13) in FIG. 8, electronic component 200 is positioned in cavity (R10) of substrate 100.

Specifically, as shown in FIG. 12, carrier 1001 made of PET (polyethylene terephthalate), for example, is arranged on one side of substrate 100 (on second surface (F2), for example). Accordingly, one opening of cavity (R10) (hole) is covered by carrier 1001. In the present embodiment, carrier 1001 is an adhesive sheet (such as tape), and is adhesive on the side of substrate 100. Carrier 1001 is adhered to substrate 100 through lamination, for example.

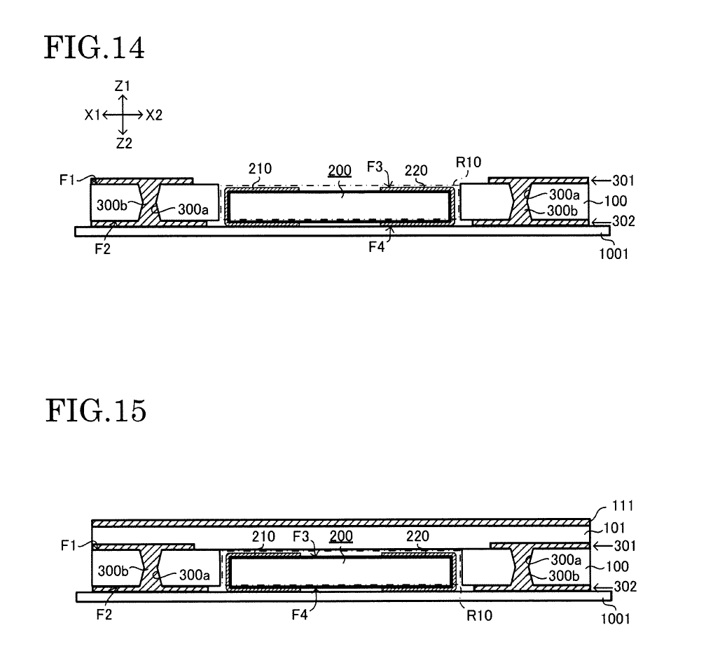

As shown in FIG. 13, electronic component 200 is placed into cavity (R10) from the side (Z1 side) opposite the covered opening of cavity (R10) (hole). Electronic component 200 is placed in cavity (R10) by a component mounter, for example. For example, electronic component 200 is held by a vacuum chuck or the like, transported to an area over cavity (R10) (Z1 side), lowered vertically from the area, and placed in cavity (R10). Accordingly, as shown in FIG. 14, electronic component 200 is positioned on carrier 1001 (adhesive sheet). When aligning electronic component 200, it is preferred to use alignment marks (301a) (see FIGS. 10A, 10B). By doing so, positional accuracy is enhanced between electronic component 200 and cavity (R10).

In step (S14) in FIG. 8, semicured insulation layer 101 (first interlayer insulation layer) is formed on first surface (F1) of substrate 100 and on third surface (F3) of electronic component 200, which are opposite (Z1 side) the covered opening of cavity (R10) (hole). Moreover, copper foil 111 (first copper foil) is formed on insulation layer 101. Insulation layer 101 is the prepreg of thermosetting epoxy resin, for example. Next, as shown in FIG. 16A, semicured insulation layer 101 is pressed so that resin flows out from insulation layer 101 into cavity (R10). Accordingly, as shown in FIG. 16B, insulator (101a) (the resin from insulation layer 101) is filled between substrate 100 and electronic component 200 in cavity (R10). Recess (R11) is formed in insulation layer 101 in region (R1) directly over gap (R0) (see FIG. 4). During that time, if the gap is narrow between substrate 100 and electronic component 200, positional shifting and unwanted inclining of electronic component 200 caused by the intensity of resin flowing into cavity (R10) seldom occur, even if electronic component 200 is not fixed securely. Insulator (101a) has a higher thermal expansion coefficient than either of substrate 100 and electronic component 200.

After insulator (101a) is filled in cavity (R10), the filled resin (insulator 101a) and electronic component 200 are preliminarily adhered. Specifically, the filled resin is heated to gain retention power to a degree that it can support electronic component 200. In doing so, electronic component 200 supported by carrier 1001 is supported by the filled resin. Carrier 1001 is removed.

At this stage, insulator (101a) (filled resin) and insulation layer 101 are only semicured, not completely cured. However, that is not the only option, and insulator (101a) and insulation layer 101 may be completely cured at this stage, for example.

In step (S15) in FIG. 8, a buildup section is formed on the second-surface (F2) side of substrate 100.

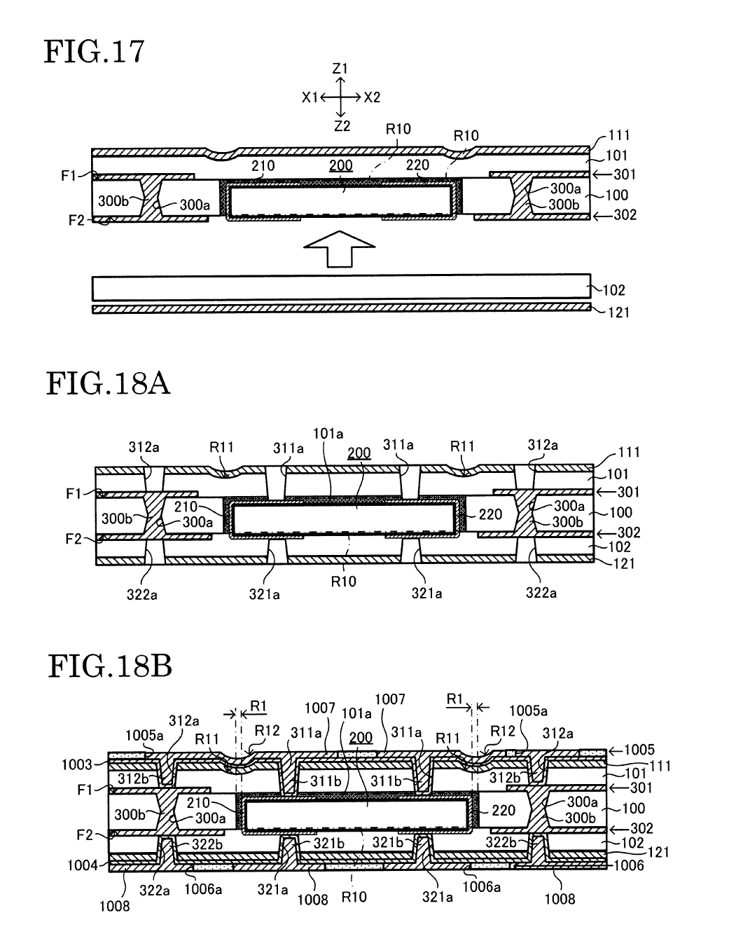

Specifically, insulation layer 102 (second interlayer insulation layer) and copper foil 121 (second copper foil) are formed on second surface (F2) of substrate 100 as shown in FIG. 17. Electrodes (210, 220) of electronic component 200 are each covered by insulation layer 102. Insulation layer 102 as prepreg is adhered to substrate 100 by pressing, for example, and insulation layers (101, 102) are each thermally cured. In the present embodiment, since the resin filled in cavity (R10) is cured after adhesive sheet (carrier 1001) is removed, insulation layers (101, 102) can be simultaneously cured. By curing insulation layers (101, 102) on both surfaces simultaneously, warping in substrate 100 is suppressed, and it is easier to make a thinner substrate 100.

In the subsequent step (S16) in FIG. 8, via conductors and conductive layers are formed.

In particular, by using a laser, for example, holes (311a, 312a) (each a via hole) are formed in insulation layer 101 and copper foil 111, and holes (321a, 322a) (each a via hole) are formed in insulation layer 102 and copper foil 121, as shown in FIG. 18A. Holes (311a, 312a) each penetrate through insulation layer 101 and copper foil 111, and holes (321a, 322a) each penetrate through insulation layer 102 and copper foil 121. Holes (311a, 321a) each reach electrode 210 or 220 of electronic component 200, and holes (312a, 322a) each reach a position directly on through-hole conductor (300b). Desmearing is conducted depending on requirements.

Using a chemical plating method, for example, electroless copper-plated films (1003, 1004), for example, are formed on copper foils (111, 121) and in holes (311a, 312a, 321a, 322a) (see FIG. 18B). Before performing electroless plating, a catalyst made of palladium or the like may be adsorbed on surfaces of insulation layers (101, 102) by immersion, for example.

Using a lithographic technique, printing or the like, plating resist 1005 having opening portions (1005a) is formed on the first-surface (F1) side main surface (on electroless plated film 1003), and plating resist 1006 having opening portions (1006a) is formed on the second-surface (F2) side main surface (on electroless plated film 1004) (see FIG. 18B). At that time, plating resist with a required pattern is used so that enlarged-width portion (E) and the like (see FIG. 5) are formed. Opening portions (1005a, 1006a) have patterns respectively corresponding to conductive layers (110, 120) (FIG. 1).

As shown in FIG. 18B, using a pattern plating method, for example, electrolytic copper platings (1007, 1008), for example, are formed respectively in opening portions (1005a, 1006a) of plating resists (1005, 1006). Specifically, copper as plating material is connected to the anode, and electroless plated films (1003, 1004) as material to be plated are connected to the cathode, and the substrate is immersed in a plating solution. DC voltage is applied between both poles to flow current so that copper is deposited on surfaces of electroless plated films (1003, 1004). Accordingly, electrolytic platings (1007, 1008) are respectively filled in holes (311a, 312a) and holes (321a, 322a) to form via conductors (311b, 312b, 321b, 322b) made of copper plating, for example.

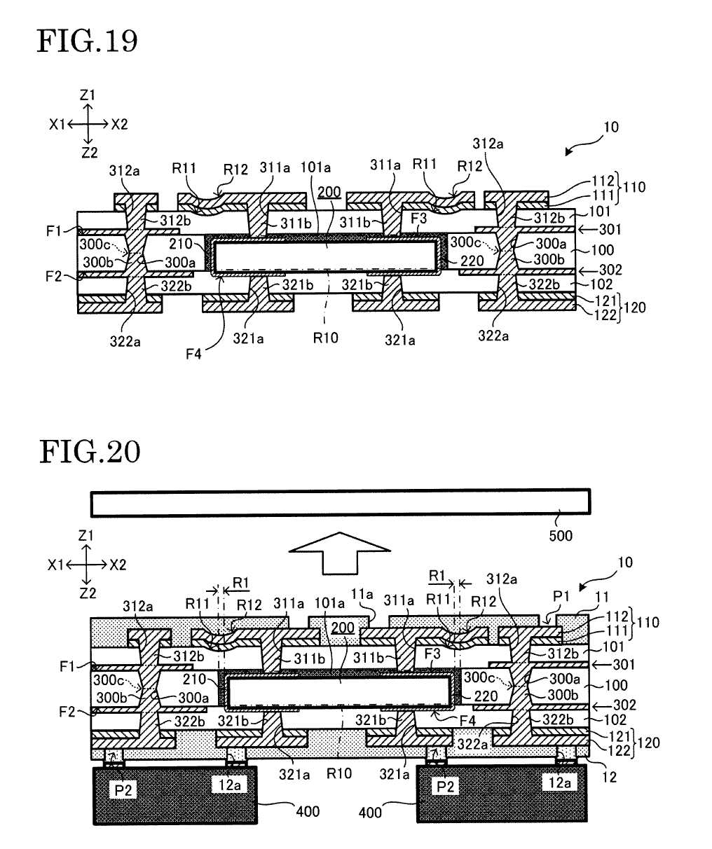

Plating resists (1005, 1006) are removed using a predetermined removal solution, for example, and unnecessary electroless plated films (1003, 1004) and copper foils (111, 121) are removed. Accordingly, conductive layers (110, 120) including conductive patterns (110a˜110d) (see FIG. 5) are formed as shown in FIG. 19.

A seed layer for electrolytic plating is not limited to electroless plated film, and sputtered film or the like may also be used as a seed layer instead of electroless plated films (1003, 1004).

In step (S17) in FIG. 8, solder resist 11 having opening portion (11a) and solder resist 12 having opening portion (12a) are respectively formed on insulation layers (101, 102) (see FIG. 1). Conductive layers (110, 120) are respectively covered by solder resists (11, 12) except for predetermined portions (such as pads (P1, P2), lands or the like) positioned in opening portions (11a, 12a). Solder resists (11, 12) are formed by screen printing, spray coating, roll coating, lamination or the like, for example.

By electrolytic plating, sputtering or the like, an anticorrosion layer made of Ni/Au film, for example, is formed on conductive layers (110, 120), in particular, on surfaces of pads (P1, P2) (see FIG. 1) not covered by solder resists (11, 12). Alternatively, an anticorrosion layer made of organic preservative film may be formed by an OSP treatment.

Accordingly, a buildup section is formed on first surface (F1) of substrate 100, where insulation layer 101, conductive layer 110 and solder resist 11 are formed, and another buildup section is formed on second surface (F2) of substrate 100, where insulation layer 102, conductive layer 120 and solder resist 12 are formed. As a result, wiring board 10 of the present embodiment (FIG. 1) is completed. Electrical testing is conducted on electronic component 200 (to check capacity, insulation or the like) if required.

The manufacturing method according to the present embodiment is suitable for manufacturing wiring boards 10. Using such a manufacturing method, excellent wiring boards 10 are obtained at low cost.

Wiring board 10 of the present embodiment may be electrically connected to electronic components or other wiring boards, for example. For example, as shown in FIG. 20, electronic component 400 (such as an IC chip) may be mounted on pad (P2) of wiring board 10 through soldering or the like. Also, wiring board 10 may be mounted on other wiring board 500 (such as a motherboard) through pad (P1). Wiring board 10 of the present embodiment may be used as a circuit board for cell phones or the like.

### Other Embodiment(s)

The planar shape of enlarged-width portion (E) in each conductive pattern is not limited to being substantially an ellipse as shown in FIG. 5, and any other shape may be employed. For example, as shown in FIG. 21A, it may be substantially a rectangle. Alternatively, as shown in FIG. 21B, it may be substantially a rhombus, or be shaped otherwise such as substantially a parallelogram.

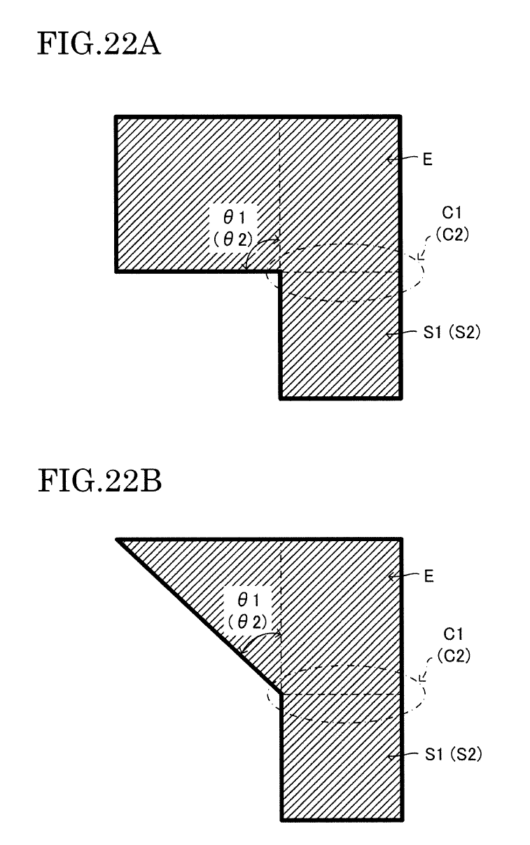

As shown in FIG. 22A, it is also an option for width-enlarging angle (θ1) at connecting point (C1) of first straight portion (S1) and enlarged-width portion (E), as well as width-enlarging angle (θ2) at connecting point (C2) of second straight portion (S2) and enlarged-width portion (E), to be set at approximately 90 degrees. However, when mitigating stress concentration and easy processing are considered, the width of a conductive pattern is preferred to be enlarged at less than approximately 90 degrees at least either at connecting point (C1) of first straight portion (S1) and enlarged-width portion (E) or connecting point (C2) of second straight portion (S2) and enlarged-width portion (E).

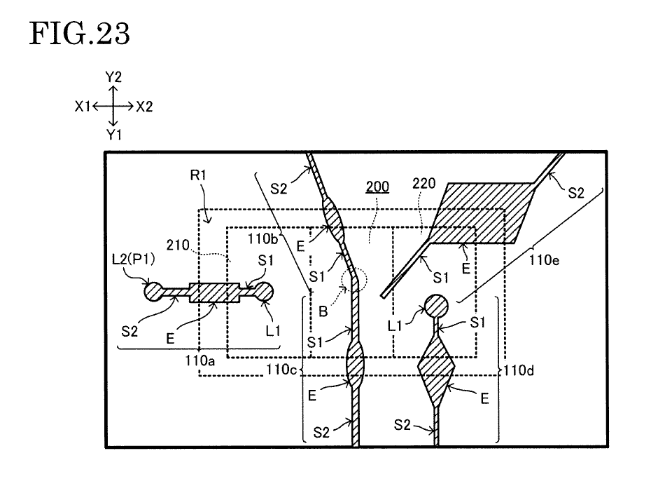

As shown in FIG. 23, a wiring board may have multiple conductive patterns (110a˜110e) which have enlarged-width portions (E) with different shapes. In the example shown in FIG. 23, the planar shape of enlarged-width portion (E) in each conductive pattern is substantially a rectangle in conductive pattern (110a), substantially an ellipse in conductive patterns (110b, 110c), substantially a rhombus in conductive pattern (110d), and substantially a parallelogram in conductive pattern (110e).

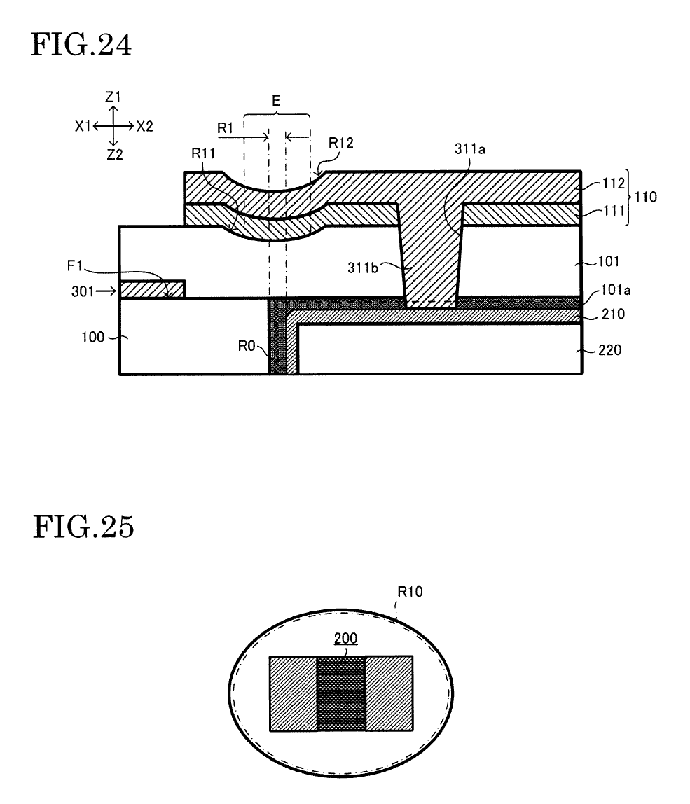

As shown in FIG. 24, it is an option for enlarged-width portion (E) to have a smaller width than recesses (R11, R12) so that only part of the conductive pattern (conductive layer 110) formed in recess (R11) is set as enlarged-width portion (E). However, to suppress breakage, it is preferred for enlarged-width portion (E) to have a greater width than recesses (R11, R12), and for enlarged-width portion (E) to be formed not only in recess (R11) but also extended to the vicinity of recess (R11) (including at least the periphery of recess (R11)) as shown in FIG. 4.

The shapes of electronic component 200 and cavity (R10) are not limited specifically. For example, as shown in FIG. 25, the opening shape of cavity (R10) may be substantially an ellipse. The shape of the main surfaces of electronic component 200 and the opening shape of cavity (R10) may be substantially a circle (substantially a perfect circle). Alternatively, other than substantially a rectangle, their shapes may be substantially a polygon such as substantially a square, substantially a regular hexagon, substantially a regular octagon and the like. The shapes of angles of the polygons are not limited specifically, and they may be, for example, substantially right, acute or obtuse, or even roundish.

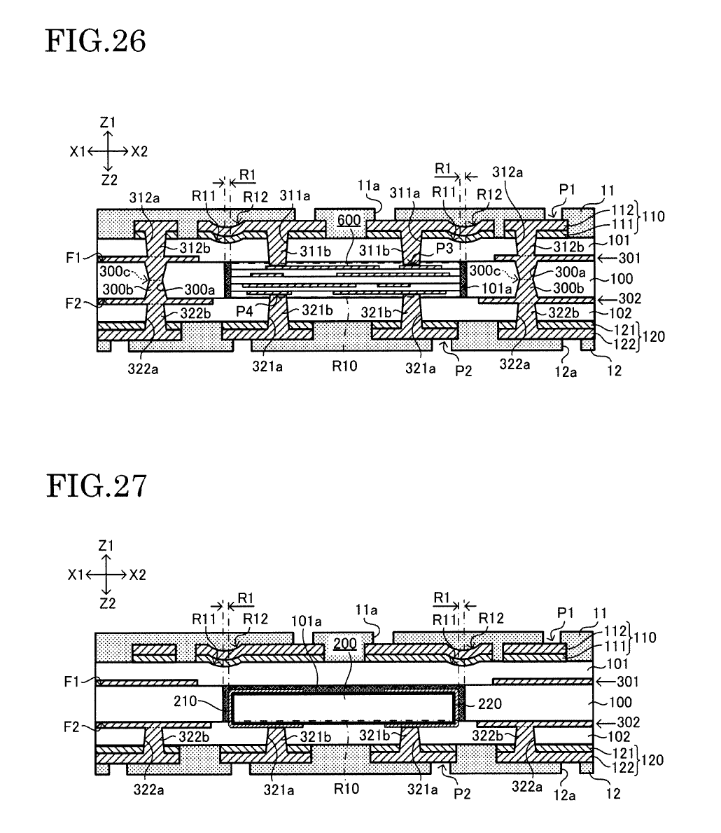

It is not necessarily electronic component 200 that is to be built into wiring board 10, but it may be other wiring board 600, for example, as shown in FIG. 26. In the example in FIG. 26, wiring board 600 is accommodated in cavity (R10), and pads (P3, P4) (external connection terminals) of wiring board 600 are electrically connected respectively to conductive layers (110, 120) (more specifically, their conductive patterns) through via conductors (311b, 321b). Each conductive layer of wiring board 600 is preferred to have fine conductive patterns, or its interlayer insulation layer between conductive layers is preferred to be set thin, for example, so that wiring board 600 has higher-density conductors than wiring board 10.

In the above embodiment, a wiring board has a double-sided via structure for electronic component 200. However, that is not the only option. For example, as shown in FIG. 27, only one side of a wiring board may have via conductors (321b) to be electrically connected to electrodes (210, 220) of electronic component 200.

In the above embodiment, a wiring board (wiring board 10) is shown having only one electronic component 200 in cavity (R10) (accommodation space for electronic component 200). However, that is not the only option. For example, it may be a wiring board having multiple electronic components 200 in cavity (R10). Multiple electronic components 200 may be arrayed along a lamination direction (direction Z) or may be arrayed along direction X or direction Y. Alternatively, multiple cavities (R10) may be formed.

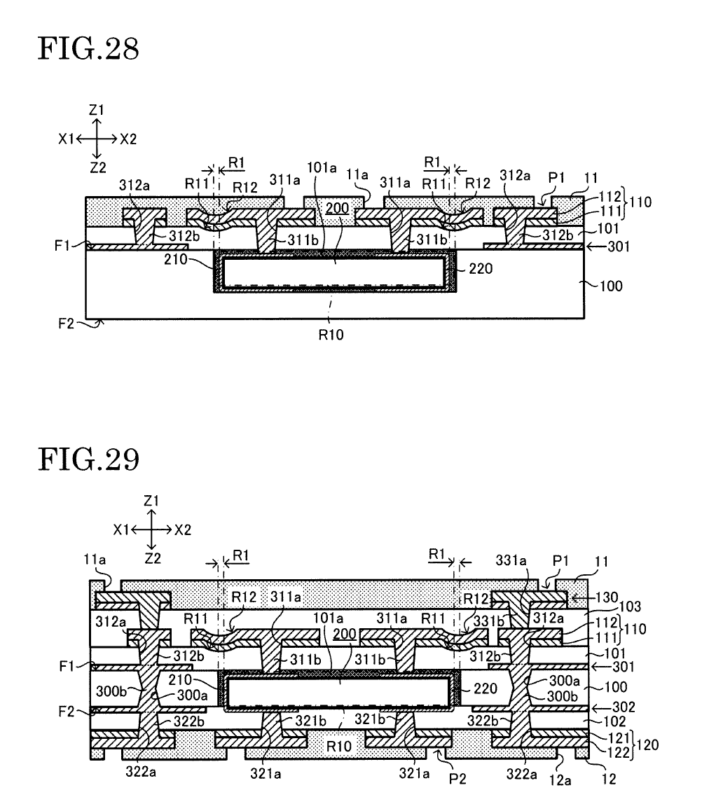

In the above embodiment, a double-sided wiring board (wiring board 10) is shown, having conductive layers on both sides of a core substrate. However, that is not the only option. For example, as shown in FIG. 28, it may be a single-sided wiring board having conductive layers only on one side of the core substrate (substrate 100).

Also, as shown in FIG. 28, for example, cavity (R10) (accommodation space for electronic component 200) may be a hole that does not penetrate through substrate 100 (a recessed portion). In such a case as well, it is considered preferable if the thickness of electronic component 200 is substantially the same as the depth of cavity (R10) (hole).

In the above embodiment, an example is shown in which the thickness of substrate 100 is substantially the same as the thickness of electronic component 200. However, that is not the only option. As shown in FIG. 28, for example, the thickness of substrate 100 may be greater than the thickness of electronic component 200.

It is an option for a wiring board to have two or more buildup layers on one side of the core substrate. As shown in FIG. 29, for example, two insulation layers (101, 103) and two conductive layers (110, 130) may be alternately laminated on the first-surface (F1) side of substrate 100. In the example shown in FIG. 29, hole (331a) (via hole) is formed in insulation layer 103, and a conductor (such as copper plating) is filled in hole (331a) so that the conductor in hole (331a) is made into via conductor (331b) (filled conductor). Conductive layer 110 on insulation layer 101 and conductive layer 130 on insulation layer 103 are electrically connected to each other by via conductor (331b).

As shown in FIG. 29, the number of buildup layers may be different on the first-surface (F1) side of substrate 100 and on the second-surface (F2) side of substrate 100. However, to mitigate stress, it is considered preferable for the number of buildup layers to be the same on the first-surface (F1) side of substrate 100 and on the second-surface (F2) side of substrate 100 so as to enhance the symmetry of upper and lower surfaces.

The structure of wiring board 10, as well as the type, performance, measurements, quality, shapes, number of layers, positioning and so forth of the elements of such a structure, may be modified freely within a scope that does not deviate from the gist of the present invention.

The electrodes (210, 220) of electronic component 200 are not limited to being U-shaped, and they may be a pair of planar electrodes that sandwich capacitor body 201.

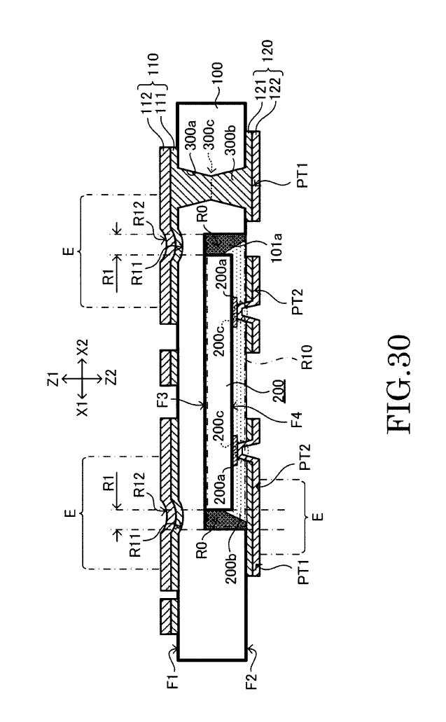

Electronic component 200 is not limited to a specific type. Any electronic component, for example, an active component such as an IC circuit along with a passive component such as a capacitor, resistor or inductor, may be used. As shown in FIG. 30, for example, electronic component 200 containing an IC chip may be positioned in cavity (R10) of substrate 100, and fixed using an insulator (adhesive agent (200b) and insulator (101a)). In the example shown in FIG. 30, electronic component 200 has pad (200a) on its fourth-surface (F4) side, and fourth surface (F4) of electronic component 200 is covered by adhesive agent (200b) (adhesive layer). In addition, conductive layer 120 has conductive pattern (PT1) positioned on substrate 100 and conductive pattern (PT2) positioned on the insulative material (adhesive agent (200b) and insulator (101a)) filled in cavity (R10). Pad (200a) of electronic component 200 and conductive pattern (PT2) are electrically connected to each other by the conductor in a via hole formed in adhesive agent (200b) (via conductor 200c). Adhesive agent (200b) is used to fix the IC chip (electronic component 200) to a support sheet during a manufacturing process, for example.

Also, in the example shown in FIG. 30, conductive layers (110, 120) each have enlarged-width portion (E) in region (R1) directly over gap (R0) between substrate 100 and electronic component 200 in cavity (R10). Here, the same as enlarged-width portion (E) in the above embodiment (see FIGS. 4 and 5), enlarged-width portion (E) of conductive layer 110 is formed in recess (R11) and its vicinity so that breakage is suppressed in conductive layer 110. On the other hand, enlarged-width portion (E) in conductive layer 120 is preferred to be positioned directly over the boundary between different materials, for example, the boundary between conductive patterns (PT1, PT2) (the boundary between substrate 100 and the insulator in cavity (R10)) or an edge of electronic component 200 (the boundary between electronic component 200 and the insulator in cavity (R10)). Since breakage tends to occur directly over the boundary of different materials because of the difference in thermal expansion coefficients between such materials, it is preferred to reinforce conductive layer 120 by enlarged-width portion (E) so that breakage is suppressed.

Via conductors (311b) and others are not limited to being filled conductors, and they may be conformal conductors, for example.

Electronic component 200 may be mounted by other methods such as wire bonding instead of via connections (via conductors (311b, 321b)).

The process for manufacturing a wiring board is not limited to the order and contents shown in FIG. 8 above. The order and contents may be modified within a scope that does not deviate from the gist of the present invention. Also, some steps may be omitted if not required, depending on usage or the like.

For example, any method may be used for forming each conductive layer. For example, any one method of the following or any combination of two or more of those may be used for forming conductive layers: panel plating, pattern plating, full-additive, semi-additive (SAP), subtractive, transfer and tenting methods.

Also, instead of a laser, wet or dry etching may be used for processing. When an etching process is employed, it is considered preferable to protect in advance with resist or the like portions which are not required to be removed.

The above embodiment and modified examples or the like may be combined freely. Selecting an appropriate combination according to usage requirements or the like is considered preferable. For example, any structure shown in FIG. 21A˜26 may be applied to any structure shown in FIGS. 27˜30.

A wiring board according to the first aspect of the present invention has the following: an insulative substrate where a cavity is formed, an electronic device positioned in the cavity, an interlayer insulation layer positioned on the insulative substrate and on the electronic device, and a conductive layer positioned on the interlayer insulation layer. In such a wiring board, the insulative material from the interlayer insulation layer is filled in a gap between the insulative substrate and the electronic device in the cavity, and the conductive layer includes a conductive pattern whose width is partially enlarged directly over the gap.

A method for manufacturing a wiring board according to the second aspect of the present invention includes the following: preparing an insulative substrate where a cavity is formed; positioning an electronic device in the cavity; forming an interlayer insulation layer on the insulative substrate and on the electronic device; filling the insulative material from the interlayer insulation layer in a gap between the insulative substrate and the electronic device in the cavity; and on the interlayer insulation layer, forming a conductive layer having a conductive pattern whose width is partially enlarged directly over the gap.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board, comprising:
an insulative substrate having a cavity portion;
an electronic device positioned in the cavity portion of the insulative substrate;
an interlayer insulation layer comprising an insulative material and formed on the insulative substrate and on the electronic device; and
a conductive layer comprising a conductive pattern and formed on the interlayer insulation layer,
wherein the insulative substrate has a gap formed with respect to the electronic device in the cavity portion, the gap between the electronic device in the cavity portion and the insulative substrate is filled with an insulator comprising the insulative material derived from the interlayer insulation layer, and the conductive pattern of the conductive layer has an enlarged-width portion across and directly over the gap.

2. The wiring board according to claim 1, wherein the interlayer insulation layer has a recess portion directly over the gap, and the enlarged-width portion of the conductive pattern is formed in the recess portion.

3. The wiring board according to claim 1, wherein the conductive pattern has a first straight portion and a second straight portion each of which has a substantially constant width, the first straight portion is connected to the second straight portion through the enlarged-width portion, and the enlarged-width portion is positioned directly over the gap and has a width greater than the substantially constant widths of the first straight portion and the second straight portion.

4. The wiring board according to claim 3, wherein the first straight portion and the enlarged-width portion form a connecting point which changes a width of the conductive pattern at an angle of less than approximately 90 degrees.

5. The wiring board according to claim 3, wherein the enlarged-width portion has the maximum width in a range of approximately 1.3 times to approximately 5 times the substantially constant width of at least one of the first straight portion and the second straight portion.

6. The wiring board according to claim 1, wherein the conductive pattern has a wiring portion and a pad portion, and the enlarged-width portion of the conductive pattern is connected to the pad portion through the wiring portion.

7. The wiring board according to claim 1, wherein the insulative material of the interlayer insulation layer has a thermal expansion coefficient which is higher than a thermal expansion coefficient of at least one of the insulative substrate and the electronic device.

8. The wiring board according to claim 1, wherein the electronic device is an electronic component, and the conductive pattern is electrically connected to an electrode of the electronic component.

9. The wiring board according to claim 1, wherein the electronic device is a second wiring board, and the conductive pattern is electrically connected to a pad of the second wiring board.

10. The wiring board according to claim 1, wherein the interlayer insulation layer comprises a core material impregnated with a resin.

11. The wiring board according to claim 1, further comprising:
an outermost layer formed on the insulative substrate on an opposite side of the conductive layer; and
a pad formed on the outermost layer and configured to mount an electronic component,
wherein the insulative substrate forms a core substrate.

12. A method for manufacturing a wiring board, comprising:
preparing an insulative substrate having a cavity portion;
positioning an electronic device in the cavity portion of the insulative substrate;
forming an interlayer insulation layer comprising an insulative material on the insulative substrate and on the electronic device;
filling a gap between the insulative substrate and the electronic device in the cavity portion with an insulator comprising the insulative material derived from the interlayer insulation layer; and
forming a conductive layer comprising a conductive pattern on the interlayer insulation layer,
wherein the forming of the conductive layer comprises forming an enlarged-width portion across and directly over the gap between the insulative substrate and the electronic device.

13. The method for manufacturing a wiring board according to claim 12, wherein the forming of the conductive layer comprises forming the enlarged-width portion on a recess portion formed in the interlayer insulation layer across and directly over the gap between the insulative substrate and the electronic device.

14. The method for manufacturing a wiring board according to claim 12, wherein the forming of the conductive layer comprises forming a first straight portion and a second straight portion each of which has a substantially constant width, the first straight portion is connected to the second straight portion through the enlarged-width portion, and the enlarged-width portion has a width greater than the substantially constant widths of the first straight portion and the second straight portion.

15. The method for manufacturing a wiring board according to claim 14, wherein the forming of the first straight portion and the enlarged-width portion comprises forming a connecting point connecting the first straight portion and the enlarged-width portion such that the connecting point changes a width of the conductive pattern at an angle of less than approximately 90 degrees.

16. The method for manufacturing a wiring board according to claim 14, wherein the forming of the first straight portion, the second straight portion and the enlarged-width portion comprises forming the enlarged-width portion having the maximum width in a range of approximately 1.3 times to approximately 5 times the substantially constant width of at least one of the first straight portion and the second straight portion.

17. The method for manufacturing a wiring board according to claim 12, wherein the forming of the conductive layer comprises forming the conductive pattern having a wiring portion and a pad portion such that the enlarged-width portion of the conductive pattern is connected to the pad portion through the wiring portion.

18. The method for manufacturing a wiring board according to claim 12, wherein the insulative material of the interlayer insulation layer has a thermal expansion coefficient which is higher than a thermal expansion coefficient of at least one of the insulative substrate and the electronic device.

19. The method for manufacturing a wiring board according to claim 12, wherein the electronic device is one of an electronic component and a second wiring board, and the conductive pattern is electrically connected to an electrode of the electronic component or a pad of the second wiring board.

20. The method for manufacturing a wiring board according to claim 12, further comprising:
forming an outermost layer on the insulative substrate on an opposite side of the conductive layer; and
forming on the outermost layer a pad configured to mount an electronic component,
wherein the insulative substrate forms a core substrate.
